(19) United States
(12) Patent Application Publication
(10) Pub. No.: US 2026/0372147 A1
(43) Pub. Date: Nov. 19, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Tae Yong LEE, Gyeonggi-do (KR); Bo Yoon YOO, Incheon (KR); Min Won PARK, Incheon (KR)

(73) Assignee: Amkor Technology Singapore Holding Pte. Ltd., Singapore (SG)

(21) Appl. No.: 19/210,860

(22) Filed: May 16, 2025

(51) Int. Cl. H10W 70/685; H05K 1/02; H05K 1/11; H10W 42/20; H10W 44/20; H10W 74/15; H10W 90/00

(52) U.S. Cl. CPC H10W 70/685; H05K 1/0243; H05K 1/111; H10W 42/20; H10W 44/20; H05K 2201/0715; H05K 2201/093; H05K 2201/09309; H05K 2201/09345; H05K 2201/09509; H05K 2201/09536; H05K 2201/10098; H10W 44/248; H10W 74/15; H10W 90/724; H10W 90/734

(57) ABSTRACT

In an example, an electronic device includes a substrate includes a first substrate side, a second substrate side opposite the first substrate side, a dielectric structure including an uppermost dielectric layer that defines the first substrate side; and an inner conductive structure including substrate inward terminals proximate to the first substrate side, and substrate outward terminals proximate to the second substrate side. An outer conductive structure is over the uppermost dielectric layer. An electronic component is coupled to the substrate proximate to the first substrate side and is coupled to the inner conductive structure. The uppermost dielectric layer includes openings that expose portions of the substrate inward terminals and the outer conductive structure is coupled to the substrate inward terminals through the openings in the uppermost dielectric layer. Other examples and related methods are also disclosed herein.

### CROSS-REFERENCES TO RELATED APPLICATIONS

Not Applicable.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a cross-sectional view of an example electronic device.

FIG. 1B shows a plan view of an example electronic device.

FIGS. 2A, 2B, 2C, 2D, and 2E show cross-sectional views of an example method for manufacturing an example electronic device.

FIG. 3A shows a cross-sectional view of an example electronic device.

FIG. 3B shows a plan view of an example electronic device.

FIGS. 4A, 4B, and 4C show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements.

### DESCRIPTION

Wireless and portable handheld communication applications are examples of applications continuing to grow and evolve with an increased effort to integrate more electronic functionality into smaller, lighter, thinner, and lower cost solutions. One of the continuing challenges for these applications is the improvement and integration of effective various power layers, ground layers, shielding layers or antennas into various product platforms.

The present description includes, among other features, structures and associated methods that relate to electronic devices using power/ground layers, shielding structures, or antennas as part of the substrate. More particularly, structures and methods are described to remove power and ground layers from within the substrate and instead, provide these layers over the substrate, such as over the top side of the substrate. In this way, the substrate is devoid of power or ground layers internal to or interposed between the upper and lower sides of the substrate. The layers can be used for other functions, such as shielding, antennas, or heat transfer enhancement. In some examples, the layers can be deposited or printed onto the substrate over an uppermost dielectric layer. In some examples, the layers are coupled to substrate inward terminals using conductive vias through the uppermost dielectric layer. In some examples, the layers can be a prefabricated structure, such as a cover or lid that is attached to the substrate with an adhesive. In some examples, the adhesive comprises a conductive adhesive. The methods and structures provide reduced manufacturing cycle time, power and ground layer design flexibility, shielding or antenna options, reduced structure complexity, and reduced manufacturing costs.

In an example, an electronic device includes a substrate including a first substrate side, a second substrate side opposite the first substrate side, a dielectric structure comprising an uppermost dielectric layer that defines the first substrate side; and an inner conductive structure includes substrate inward terminals proximate to the first substrate side, and substrate outward terminals proximate to the second substrate side. An outer conductive structure is over the uppermost dielectric layer. An electronic component is coupled to the substrate proximate to the first substrate side and is coupled to the inner conductive structure. In the present example, the uppermost dielectric layer comprises openings that expose portions of the substrate inward terminals and the outer conductive structure is coupled to the substrate inward terminals through the openings in the uppermost dielectric layer.

In an example, the outer conductive structure comprises a first portion comprising a power layer and a second portion comprising a ground layer. In an example, the only power layer for the electronic device consists of the first portion of the outer conductive structure and the only ground layer for the electronic device consists of the second portion of the outer conductive structure.

In an example, an electronic device includes a substrate including a first substrate side, a second substrate side opposite to the first substrate side, a dielectric structure comprising an uppermost dielectric layer that defines the first substrate side; and an inner conductive structure including substrate inward terminals proximate to the first substrate side, signal patterns proximate to the first substrate side, and substrate outward terminals proximate to the second substrate side. An outer conductive structure is over the uppermost dielectric layer. An electronic component is coupled to the substrate proximate to the first substrate side and is coupled to the inner conductive structure. In the present example, the outer conductive structure partially covers the first substrate side so that a portion of the uppermost dielectric layer is exposed from the outer conductive structure, the uppermost dielectric layer comprises openings that expose portions of the substrate inward terminals, and the outer conductive structure is coupled to the substrate inward terminals through the openings in the uppermost dielectric layer.

In an example, a method of manufacturing an electronic device includes providing a substrate including a first substrate side, a second substrate side opposite to the first substrate side, a dielectric structure comprising an uppermost dielectric layer that defines the first substrate side; and an inner conductive structure including substrate inward terminals proximate to the first substrate side, signal patterns proximate to the first substrate side, and substrate outward terminals proximate to the second substrate side. The method includes providing an outer conductive structure over the uppermost dielectric layer. The method includes coupling an electronic component to the substrate proximate to the first substrate side and coupled to the inner conductive structure. In the present example, the outer conductive structure comprises an outer conductive structure opening that exposes the substrate inward terminals, the electronic component is coupled to the substrate inward terminals through the outer conductive structure opening, the uppermost dielectric layer comprises openings that expose portions of the substrate inward terminals and the outer conductive structure is coupled to the substrate inward terminals through the openings in the uppermost dielectric layer.

Other examples are included in the present disclosure. Such examples may be found in the figures, in the claims, or in the description of the present disclosure.

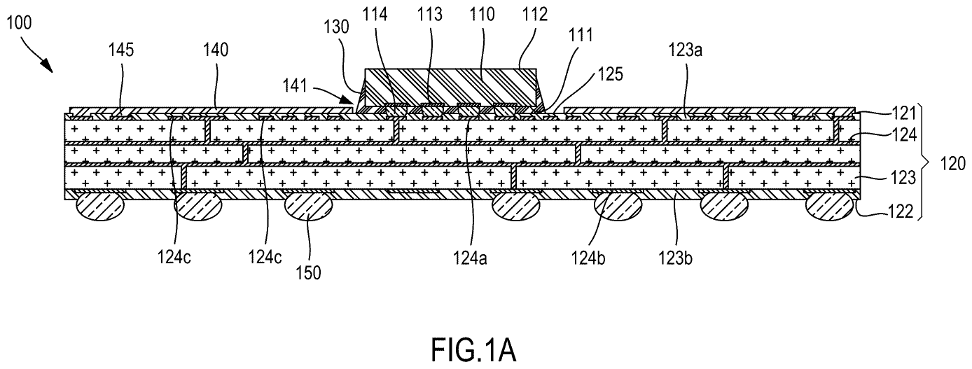

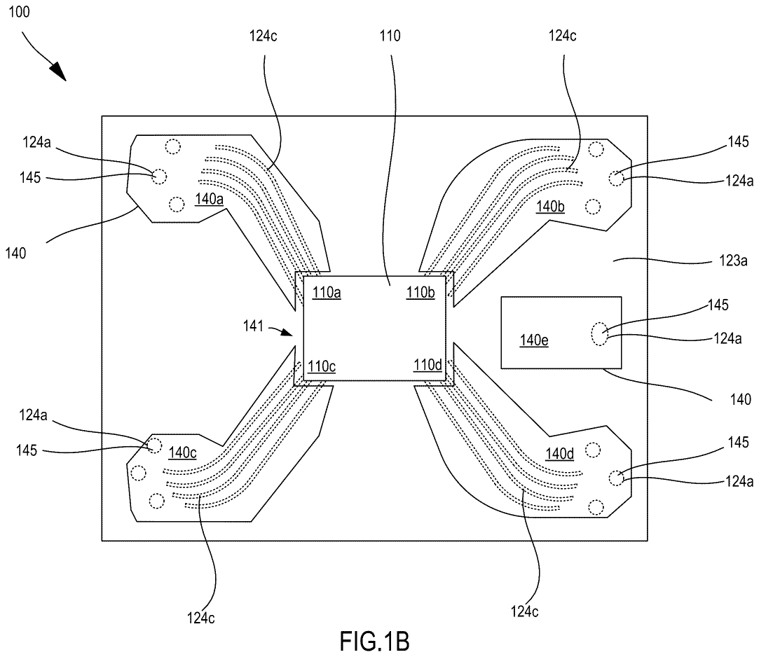

FIG. 1A shows a cross-sectional view of an example electronic device 100. In the example shown in FIG. 1A, electronic device 100 can comprise electronic component 110, substrate 120, underfill 130, conductive material 140, and external interconnects 150. FIG. 1B shows a plan view of electronic device 100.

Electronic component 110 can comprise first electronic component side 111, second electronic component side 112, electronic component contact pad 113, and electronic component connector 114. In the present example, conductive material 140 can be a discontinuous structure and electronic component 110 can be coupled to substrate 120 through an opening 141 in conductive material 140. Opening 141 can comprise or be referred to as a gap or an outer conductive structure opening.

Substrate 120 can comprise first substrate side 121, second substrate side 122, dielectric structure 123, and inner conductive structure 124. Dielectric structure 123 can comprise uppermost dielectric layer 123a and lowermost dielectric layer 123b. Inner conductive structure 124 can comprise substrate inward terminals 124a, signal patterns 124c, and substrate outward terminals 124b. In some examples, conductive material 140 can comprise conductive vias 145 coupled to inner conductive structure 124 at first substrate side 121. Conductive material 140 and conductive vias 145 are an example of an outer conductive structure that can be configured as one or more of a power layer, a ground layer, a shielding structure, or a heat transfer structure. In the present example, conductive material 140 conforms to uppermost dielectric layer 123a. That is, conductive material 140 is other than a lid or cover structure that is locally attached to substrate 120 but is otherwise spaced apart from first substrate side 121 and covers electronic component 110. In some examples, conductive material 140 contacts uppermost dielectric layer 123a and conductive vias 145 along its entire lateral extent and does not extend laterally and vertically to cover or laterally overlap the electronic component 110.

FIG. 1B shows a top plan view of an example electronic device. In some examples, FIG. 1B can be a plan view of electronic device 100 from FIG. 1A. In the example shown in FIG. 1B, electronic component 110 can be placed proximate to the center of substrate 120 and can be coupled to substrate inward terminals 124a. In other examples, electronic component 110 can be offset toward one side of substrate 120. For example, in mobile devices or compact package designs, electronic component 110 can be placed near an edge of substrate 120, with connectors or interfaces on the opposite side. If the chip is large or multiple chips are included, multiple chips can be arranged, and the pattern of conductive material 140 can be better optimized.

In some examples, conductive material 140 can include multiple parts or portions. In some examples, conductive material 140 comprises a patterned structure to provide the multiple parts. In the present example, FIG. 1B illustrates conductive material 140 with portion 140a, portion, 140b, portion 140c, portion 140d, and portion 140e. In some examples, portions 140a-140d can comprise power layers and portion 140e can comprise a ground layer. Other configurations are possible with portions 140a-140e. One or more of portion 140a, portion 140b, and portion 140c can be an example of a first portion or a second portion of a conductive structure. Portion 140e can be an example of a second portion or a first portion of the conductive structure. In some examples, portions 140a-140d are provided in a symmetrical pattern in the top plan view where each portion extends outward from a corner edge 110a, 110b, 110c, and 110d respectively of electronic component 110. In some examples, conductive material 140 only partially covers first substrate side 121 so that portions of uppermost dielectric layer 123a is exposed from conductive material 140.

In some examples, electronic device 100 can have an arrangement where uppermost dielectric layer 123a covers the entire first substrate side 121 of substrate 120, while conductive material 140 and substrate inward terminals 124a are coupled through conductive vias 145 within openings 125. However, in certain examples, such as for critical signal integrity regions, uppermost dielectric layer 123a can be minimized to expose more conductive patterns (for example, RF or high-speed data areas). In other examples, uppermost dielectric layer 123a can be multi-layered for improved EMI shielding or insulation.

In some examples, electronic device 100 can have substrate inward terminals 124a arranged around electronic component 110 uniformly or concentrated in specific regions. For example, in a power-intensive system, certain regions can include more terminals for power and ground. For high-speed signals, substrate inward terminals 124a can be placed along the shortest possible route.

In some examples, electronic device 100 can have conductive material 140 so it covers substrate inward terminals 124a and signal patterns 124c. Design can vary, and conductive material 140 can also be distributed more widely or only in selected regions according to specific application requirements. For instance, in high-power applications, conductive material 140 can form a power-only path separated from signal patterns. Multiple layers of conductive patterns can be arranged for optimization. In wireless applications, conductive material 140 can form an antenna pattern.

In some examples, electronic device 100 can comprise conductive vias 145 coupled to conductive material 140 in specific regions for interlayer connections. In other examples, the number or arrangement of conductive vias 145 can be modified to reduce cost or optimize signal paths, or additional vias can be added to carry high current for power or ground paths.

As described above, the present disclosure provides a more optimized structure enabling maintenance of signal integrity and power integrity without mandating a power layer or a ground layer internal to substrate 120. By coating or depositing conductive material 140 or adding conductive vias 145 in certain regions, signals and power can be routed more effectively. Rather than adding separate copper layers for power and ground internal to substrate 120, the present disclosure allows flexible substrate designs by providing conductive material 140 configured for signal and power delivery.

In addition, manufacturing can be simplified or less expensive compared to standard multilayer substrate processes. This beneficially provides, among other things, stable operation without dedicated power or ground layers internal to the substrate, reducing layer count while lowering power loss or signal interference. This provides a simplified substrate structure at a lower cost.

Additionally, the present disclosure positions conductive vias 145 at pre-selected locations for effective interlayer connections, providing improved signal delivery and higher power transmission efficiency. Conventional methods often needed extra wiring for interlayer connections, but by combining conductive material 140 and conductive vias 145, wiring design flexibility can increase. This approach can enable higher-speed or smaller packages with improved designs.

In some examples, substrate 120 includes uppermost dielectric layer 123a arranged so substrate inward terminals 124a can be exposed through openings 125, permitting easy interfacing with external connectors or devices. This can optimize external electronic component interfaces by supporting connector pins, solder balls, or wire bonding effectively. Previous techniques often required routing power inside the substrate, but the present disclosure offers direct conductive material connections to external regions for enhanced power, ground, or signal transmission efficiency.

Thus, it is seen that the present disclosure can enhance substrate design flexibility, provide more efficient signal and power routing than older methods, reduce manufacturing cost, simplify processes, and improve reliability.

In some examples, electronic device 100 can support various modifications since signal and power integrity are maintained without a dedicated power layer or ground layer. For example, for high-speed data, the number of conductive vias 145 can be minimized, and the pattern of conductive material 140 can be designed for faster signals. EMI shielding can be enhanced by partially opening uppermost dielectric layer 123a.

For smaller, low-power packages, conductive material 140 can be applied only where needed to keep substrate 120 light. In some examples, the thickness of uppermost dielectric layer 123a can be reduced for smaller devices.

In some examples, to decrease power loss, the thickness of conductive material 140 can be increased or stacked in multiple layers for higher power efficiency. Conductive vias 145 can be included to provide more stable power delivery.

In accordance with the present description, substrate 120 is devoid of power and ground layers between uppermost dielectric layer 123a and lowermost dielectric layer 123b. The only power or ground layers that exist with substrate 120 consists of the power or ground layers that are located on or over first substrate side 121. In some examples, inner conductive structure 124 consists of a signal distribution structure or network and the power layer and/or the ground layer are external to inner conductive structure 124.

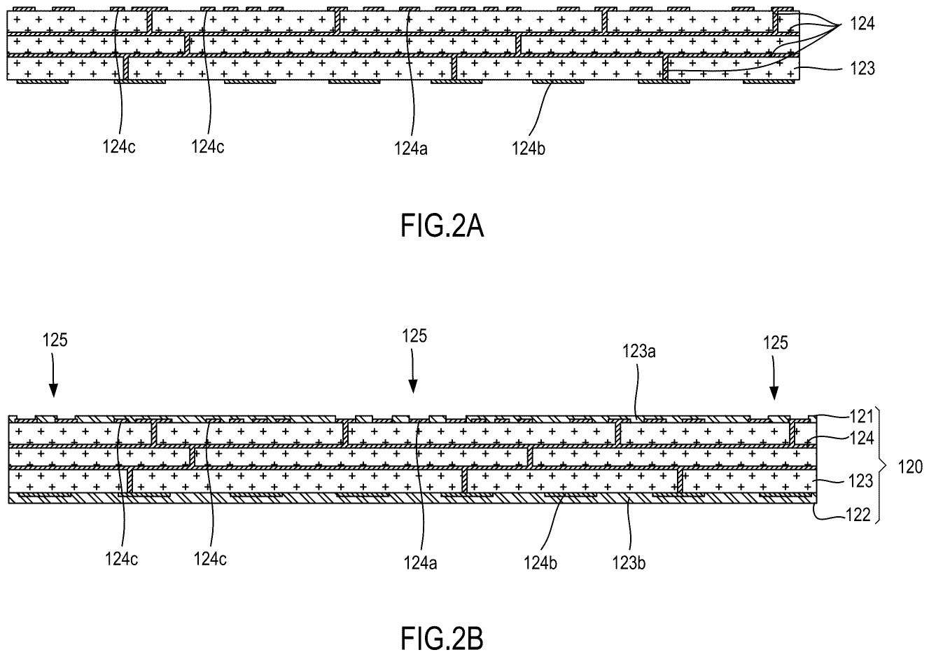

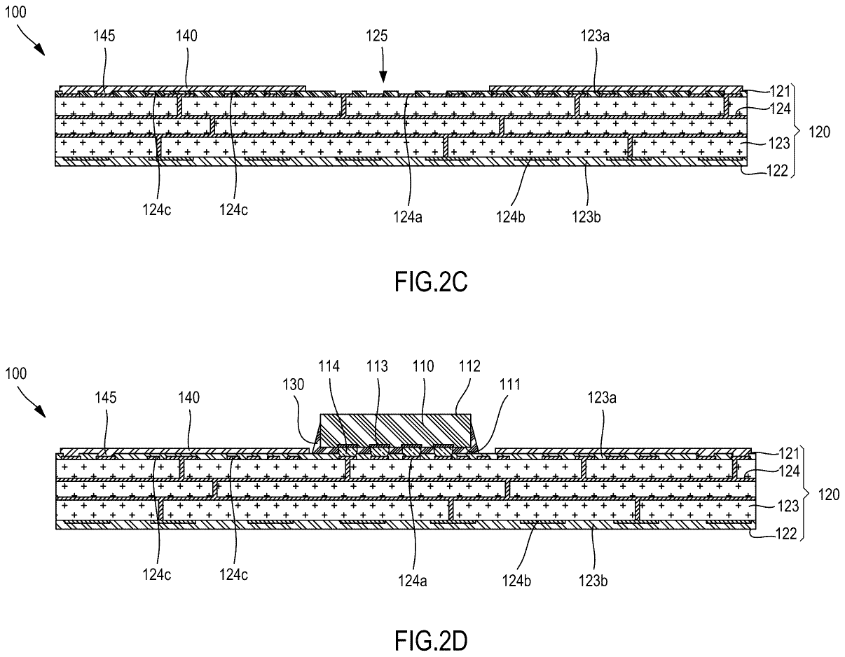

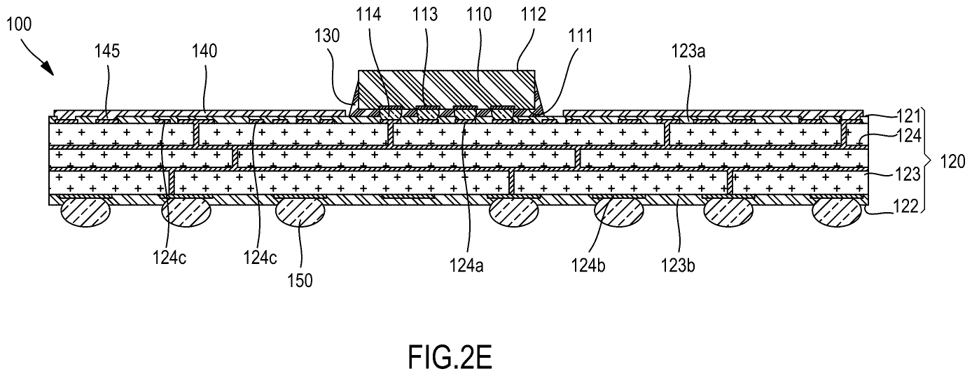

FIGS. 2A, 2B, 2C, 2D, and 2E show cross-sectional views of an example method for manufacturing an electronic device, such as example electronic device 100. FIG. 2A shows a cross-sectional view of substrate 120 of electronic device 100 at an early stage of manufacture. In the present disclosure, electronic device 100 can comprise or be referred to as an electronic apparatus, electronic package, semiconductor device, semiconductor package, device, or package.

In the example shown in FIG. 2A, a signal distribution network or structure can be provided as part of substrate 120. For example, this can comprise forming and patterning one or more dielectric structures and one or more conductive structures to provide the signal distribution structure. The signal distribution structure can also comprise or be referred to as a redistribution layer (RDL), a RDL stack, a redistribution structure, or an interposer.

In some examples, substrate 120 can comprise a rigid laminate substrate, a flexible laminate substrate, a RDL substrate, a coreless substrate, a ceramic substrate, a glass substrate, or a silicon (Si) substrate.

In the present example, substrate 120 can comprise dielectric structure 123 and inner conductive structure 124. With reference to FIG. 2B, substrate 120 can comprise first substrate side 121, which can be defined by uppermost dielectric layer 123a of dielectric structure 123, and second substrate side 122, which can be defined by lowermost dielectric layer 123b of dielectric structure 123. In some examples, inner conductive structure 124 can comprise substrate inward terminals 124a and signal patterns 124c at or proximate to first substrate side 121, and substrate outward terminals 124b at or proximate to second substrate side 122.

In some examples, inner conductive structure 124 can be provided through various processes including, for example, electroplating, electroless plating, chemical vapor deposition (CVD), metal organic chemical vapor deposition (MOCVD), sputtering, physical vapor deposition (PVD), atomic layer deposition (ALD), printing, screen printing, lithography, or similar processes known to one of ordinary skill in the art. In the present disclosure, inner conductive structure 124 can be one or more conductive layers defining signal distribution elements and can comprise or be referred to as traces, vias, pads, conductive paths, or under-bumped metallization (UBM).

In some examples, inner conductive structure 124 can provide an electrical path through a signal distribution structure in a vertical manner or in a vertical-plus-horizontal manner between electronic components (or other components). For example, inner conductive structure 124 can provide a lateral (horizontal) electrical path between electronic component 110 (or other components) through the signal distribution structure of substrate 120.

In some examples, inner conductive structure 124 can comprise conductive layers, traces, pads, through substrate vias (TSVs), through substrate groove (TSGs), vias, RDL, wiring patterns, circuit patterns, signal distribution layers, under-bump metallization (UBM), land layers, or bond pad layers. In some examples, inner conductive structure 124 can comprise copper (Cu), gold (Au), silver (Ag), or nickel (Ni). Inner conductive structure 124 can also comprise aluminum (Al), titanium (Ti), chromium (Cr), tungsten (W), or palladium (Pd).

In some examples, inner conductive structure 124 can transmit or redistribute signals, current, or voltage within substrate 120. In some examples, inner conductive structure 124 can extend through substrate 120 to connect substrate outward terminals 124b, substrate inward terminals 124a, and signal patterns with one another.

In some examples, substrate outward terminals 124b can be provided at or proximate to second substrate side 122 of substrate 120. Substrate outward terminals 124b can be coupled to inner conductive structure 124 and regarded as part of inner conductive structure 124. In some examples, substrate outward terminals 124b can be partially exposed by dielectric structure 123. For example, substrate outward terminals 124b can be exposed through openings in lower most dielectric layer 123b. In some examples, substrate outward terminals 124b can be provided in multiple patterns including discrete or individual patterns. Substrate outward terminals 124b can comprise pads, bond pads, two-step pads, lands, UBM, wiring layers, or metal layers. Substrate outward terminals 124b can comprise Cu, Al, Pd, Ti, W, Ti/W, Ni, Au, or Ag. Substrate outward terminals 124b can be provided through sputtering, electroless plating, electroplating, PVD, CVD, MOCVD, ALD, low-pressure chemical vapor deposition (LPCVD), or plasma-enhanced chemical vapor deposition (PECVD). Substrate outward terminals 124b can be connected to substrate inward terminals 124a through inner conductive structure 124.

In some examples, substrate outward terminals 124b can be provided by forming a metal seed layer covering the upper surface of a carrier, then applying a mask pattern on the seed layer, and then plating by using the seed layer as a seed. For example, the mask pattern can comprise photoresist. The mask pattern can be removed after substrate outward terminals 124b are formed. In some examples, the thickness of substrate outward terminals 124b can range from approximately 1 micrometer (micron) to approximately 2000 microns.

Dielectric structure 123 (including uppermost dielectric layer 123a and lowermost dielectric layer 123b) can be provided over substrate outward terminals 124b. In some examples, dielectric structure 123 can be interleaved with inner conductive structure 124. After dielectric structure 123 covers inner conductive structure 124, an opening can be provided to expose inner conductive structure 124. For example, the opening can be provided by creating a mask pattern on top of dielectric structure 123, then removing the exposed portion of dielectric structure 123 through etching. In some examples, the opening can be referred to as an aperture or a hole. In some examples, dielectric structure 123 can comprise or be referred to as a dielectric layer, a coreless layer, or a filler-free layer. For example, dielectric structure 123 can comprise polyimide (PI), benzocyclobutene (BCB), polybenzoxazole (PBO), resin, or Ajinomoto Buildup Film (ABF) as an electrically insulating material. Dielectric structure 123 can comprise resin, mold, ceramic, glass, or silicon. In some examples, dielectric structure 123 can be provided through spin coating, spray coating, printing, sintering, thermal oxidation, PVD, CVD, MOCVD, ALD, LPCVD, PECVD, sheet lamination, or vaporization. In some examples, the thickness of dielectric structure 123 can range from approximately 10 microns to approximately 2000 microns.

Substrate inward terminals 124a can be provided at or proximate to first substrate side 121 of substrate 120. Substrate inward terminals 124a can be coupled to inner conductive structure 124 and regarded as part of inner conductive structure 124. In some examples, substrate inward terminals 124a can be partially exposed by dielectric structure 123. For example, substrate inward terminals 124a can be exposed through openings in uppermost dielectric layer 123a. In some examples, substrate inward terminals 124a can be provided with multiple patterns on first substrate side 121 including discrete or individual patterns.

In some examples, substrate inward terminals 124a can comprise pads, lands, UBM, or studs. In some examples, substrate inward terminals 124a can comprise Cu, Au, Ag, or Ni. Substrate inward terminals 124a can comprise corresponding elements, features, materials, or manufacturing methods similar to previously described substrate outward terminals 124b. In some examples, the overall thickness of inner conductive structure 124 can range from approximately 1 micron to approximately 2000 microns.

In some examples, substrate inward terminals 124a can be connected to an internal wiring network provided by inner conductive structure 124 within substrate 120 and deliver signals or power to an internal device such as a semiconductor chip. In some examples, inner conductive structure 124 comprises signal patterns 124c proximate to first substrate side 121. In some examples, conductive material 140 overlies signal patterns 124c. In some examples, substrate outward terminals 124b can be connected to external systems, interfacing with external boards or packages for external signal and power interfaces.

In the example shown in FIG. 2A, substrate 120 is depicted with three layers of dielectric structure 123 and four layers of inner conductive structure 124. However, the number of layers in dielectric structure 123 or inner conductive structure 124 can be fewer or more. One or more layers or elements of inner conductive structure 124 can be interleaved with dielectric structure 123. Substrate inward terminals 124a and substrate outward terminals 124b can be spaced apart from one another in row or column directions on the inside and outside of substrate 120. In some examples, the overall thickness of substrate 120 can range from approximately 10 microns to approximately 2000 microns.

FIG. 2B shows a cross-sectional view of substrate 120 of electronic device 100 at a later stage of manufacture. In the example shown in FIG. 2B, dielectric structure 123 can comprise uppermost dielectric layer 123a and lowermost dielectric layer 123b. After inner conductive structure 124 and dielectric structure 123 are arranged as a stacked structure inside substrate 120, uppermost dielectric layer 123a and lowermost dielectric layer 123b can be provided to define first substrate side 121 and second substrate side 122 respectively. In some examples, uppermost dielectric layer 123a and lowermost dielectric layer 123b comprise protective and insulating materials or layers.

Uppermost dielectric layer 123a and lowermost dielectric layer 123b can be referred to as solder masks or solder resists. Uppermost dielectric layer 123a and lowermost dielectric layer 123b can function as protective coatings, formed thinly on the surfaces of a printed circuit board (PCB) or semiconductor package substrate, protecting circuit patterns from external environments and preventing unintended soldering during soldering processes. They can also prevent solder from spreading on the substrate surface so soldering occurs only at specific regions, aiding long-term reliability.

Uppermost dielectric layer 123a and lowermost dielectric layer 123b can be formed through multiple manufacturing steps. First, the surface of substrate 120 can be cleaned to remove foreign matter, possibly by chemical or plasma processes. After cleaning, material for uppermost dielectric layer 123a and lowermost dielectric layer 123b can be applied (liquid form or film form). A liquid form can be applied by spray or screen printing, and a film can be attached by lamination. Once applied, these dielectric layers can be exposed with ultraviolet light to form a desired pattern, developed to remove unwanted portions, and cured with heat or ultraviolet light. Through this process, uppermost dielectric layer 123a and lowermost dielectric layer 123b can be attached to the surface of substrate 120 and protect circuit patterns.

Uppermost dielectric layer 123a and lowermost dielectric layer 123b can prevent electrical short circuits among circuit patterns. As the spacing among patterns inside substrate 120 reduces in size, solder can flow into unplanned locations and cause short circuits. These dielectric layers can block flow and enhance reliability. They can also control soldering so it occurs only at certain locations, preventing solder from spreading to unwanted regions. Uppermost dielectric layer 123a and lowermost dielectric layer 123b can protect circuit patterns from moisture, contaminants, and chemicals, which can be valuable for devices in high-temperature or high-humidity environments requiring corrosion and chemical resistance. They can also provide mechanical protection from external friction or impact.

Uppermost dielectric layer 123a and lowermost dielectric layer 123b can comprise polymer materials based on photosensitive or thermoset resins. Photosensitive epoxy can be cost-effective and allow uniform coatings, and photosensitive polyimide can maintain stable characteristics in high-temperature environments. A liquid photoimageable (LPI) approach can form fine patterns at high resolution, suitable for high-density interconnect (HDI) substrates requiring precise patterns.

Uppermost dielectric layer 123a and lowermost dielectric layer 123b can comprise different materials from dielectric structure 123 inside substrate 120. While dielectric structure 123 inside maintains low dielectric loss and high insulation for signal transmission, uppermost dielectric layer 123a and lowermost dielectric layer 123b focus on mechanical protection and soldering control. This design can increase reliability and long-term stability for substrate 120.

In some examples, uppermost dielectric layer 123a can comprise openings 125. In some examples and with reference to FIG. 1A, uppermost dielectric layer 123a can be partially removed at certain regions to form openings 125 so substrate inward terminals 124a, conductive material 140, and electronic component 110 can be coupled together. In some examples, the top of substrate 120 can be coated with uppermost dielectric layer 123a, and openings 125 can be formed at certain locations to connect with substrate inward terminals 124a. This corresponds to the portion connecting with an internal signal or power pattern of substrate 120. In some examples, openings 125 can be formed using photolithographic and etch processes.

In some examples, openings 125 provide an interface at the top of substrate 120 for one or more electronic components, such as semiconductor chips, packages, external connectors or combinations thereof, to contact signal or power patterns internal to substrate 120 through openings 125.

Lowermost dielectric layer 123b can also comprise openings to expose substrate outward terminals 124b for external interconnects 150 (see FIG. 2E). In some examples, the bottom of substrate 120 can require electrical connection with an external circuit (for example, a PCB, system board, or test board), so these openings can be formed in lowermost dielectric layer 123b. For example, this can be the region where external interconnects 150 connect. Substrate outward terminals 124b can be exposed by partially removing lowermost dielectric layer 123b to ensure stable electrical connection with an external board or package. In some examples, photolithographic and etch processes can be used to form the openings in lowermost dielectric layer 123b.

In some examples, substrate 120 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si₃N₄), silicon oxide (SiO₂), or SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this disclosure can also comprise an RDL substrate.

In some examples, substrate 120 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can rereferred to as a printed circuit board (PCB) or a laminate substrate. Such pre-formed substrate can be formed through a semi-additive or modified-semi-additive process. Other substrates in this disclosure can also comprise a pre-formed substrate.

FIG. 2C shows a cross-sectional view of electronic device 100 at a later stage of manufacture. In the example shown in FIG. 2C, conductive material 140 can be provided on first substrate side 121 of substrate 120. In the present example, conductive material 140 can comprise conductive vias 145 that extend into openings 125 to couple to selected ones of substrate inward terminals 124a. In accordance with the present description, conductive material 140 and conductive vias 145 can replace conventional power layers and ground layers, while enabling stable signal and power delivery, shielding, antenna formation, and passive pattern formation within substrate 120.

In some examples, conductive material 140 can be formed through coating, plating, printing, or attaching a metal piece, plate, or lid. Conductive material 140 can be configured to provide electrical connections without separate power or ground layers provided internal to substrate 120.

In some examples, conductive material 140 can be formed by spraying or dispensing conductive paste or conductive nano-ink onto certain regions of substrate 120, followed by curing for stable conductivity. This coating approach can be relatively simple and selectively applied only where conductive material 140 is needed, using, for example, screening, printing, or masking techniques.

In some examples, conductive material 140 can be formed by depositing a conductive metal comprising Cu, Ni, or Ag on a portion of substrate 120 using an electrochemical process, such as electroplating or electroless plating. In some examples, a multilayer structure can be created using multiple layers of conductive material 140, which can layered on top of each other, or can be separated by additional dielectric layers in an interleaved manner.

In some examples, conductive material 140 can be formed by printing a conductive ink pattern on substrate 120. For example, screen printing or inkjet printing can be used. This can cost less than conventional copper wiring processes. High-resolution printing can form fine patterns, useful for radio frequency (RF) circuits or antenna structures. In some examples, conductive material 140 comprises a patterned structure over uppermost dielectric layer 123a that can be formed using masking and etching techniques or masking and deposition techniques.

Conductive material 140 can function beyond simple wiring. Even without dedicated power or ground layers, conductive material 140 can maintain signal integrity in certain domains and minimize power loss in other applications.

In some examples, conductive material 140 can block electromagnetic interference (EMI). It can reflect or absorb electromagnetic waves in selected regions of the electronic device. In some examples, conductive material 140 can be configured as an antenna pattern for transmitting and receiving RF signals, which can provide a more lightweight or simpler approach compared to copper foil antennas. For example, when conductive material 140 implements an EMI shielding layer, it can selectively cover regions around high-speed signal lines or an RF module to effectively block electromagnetic interference. It can also form a fifth Generation Wireless Cellular Network (5G) antenna or other wireless communication antennas (for example, GPS, Bluetooth, or Wi-Fi). By adjusting thickness, shape, or metal composition of conductive material 140, antenna characteristics can be optimized. Additionally, miniature patterns can be formed to create passive components (for example, inductors, capacitors, resistors), reducing the need for separately mounted parts and enabling on-package integration in a semiconductor package.

Conductive vias 145 can be configured to route signals or power through conductive material 140 to internal patterns in substrate 120. In some example, conductive vias 145 can comprise a metal (including the same materials as conductive material 140) substrate inward terminals 124a connect with conductive material 140, enhancing signal integrity and power integrity without dedicated power and ground layers.

Conductive vias 145 can be configured as conductive paths for substrate 120 linking the network of layers electrically to conductive material 140. In some examples, conductive vias 145 can be formed by plating metal into opening 125, thereby creating electrical connections. In some examples, copper plating can be used for power or signal routing. In some examples, conductive vias 145 can be formed by depositing or coating conductive material in openings 125 using, for example, high density interconnect (HDI) technology. In certain examples, conductive vias 145 can fill openings 125 with nano ink or conductive paste followed by curing process to control, for example, conductivity.

In accordance with the present description, conductive vias 145 provide interlayer connections for signal and power nodes and couple conductive material 140 to internal signal patterns of substrate 120. This configuration delivers signals and power from the top to the bottom of substrate 120. Since separate power and ground layers are removed from within substrate 120 and instead, formed over first substrate side 121, conductive vias 145 can effectively connect power domains and signal paths, meaning conductive material 140 is connected to internal signal patterns by way of conductive vias 145.

Some regions of conductive material 140 can be arranged to maintain signal integrity and power integrity, also blocking EMI if conventional power and ground layers are removed. In some examples, conductive material 140 can be applied to net regions to preserve signal integrity where high-speed signals propagate.

In some examples, conductive material 140 can be placed in a power domain region of substrate 120. With substrate 120 provided without an internal power layer, conductive material 140 can be formed where power distribution is needed, providing stable power integration for high-current paths.

In some examples, conductive material 140 can provide power or ground shielding. Conductive material 140 can act as a shielding layer for EMI. When previous power or ground layers that offered EMI shielding are excluded from substrate 120, conductive material 140 can reduce signal interference. Conductive material 140 can cover or surround certain high-speed signal paths or serve as a ground plane.

In some examples, conductive material 140 can be placed around substrate inward terminals 124a of uppermost dielectric layer 123a. Substrate inward terminals 124a connect with electronic component 110, so conductive material 140 can be aligned with critical nets and power domains to maintain power and signal integrity, potentially covering or overlapping substrate inward terminals 124a.

In some examples, the thickness of conductive material 140 can range from approximately 1 micron to approximately 2000 microns.

FIG. 2D shows a cross-sectional view of electronic device 100 at a later stage of manufacture. In the example shown in FIG. 2D, electronic component 110 can be placed on first substrate side 121 of substrate 120. In some examples, electronic component 110 can placed in a central location adjacent to a portion of openings 125 of uppermost dielectric layer 123a.

In some examples, electronic component 110 can comprise first electronic component side 111, second electronic component side 112 opposite to first electronic component side 111, electronic component contact pads 113, and connectors 114. Electronic component 110 can be coupled to substrate inward terminals 124a of substrate 120 in a flip-chip configuration. In some examples, the underside of electronic component 110 (first electronic component side 111) can be considered the active side, and the upper side (second electronic component side 112) can be considered the inactive side. In a scenario where electronic component 110 can be a semiconductor die, the active side of electronic component 110 can face substrate 120, and the inactive side can face away from substrate 120. In some examples, electronic component 110 can comprise or be referred to as a die, chip, package, or passive. In some examples, it can comprise a digital signal processor (DSP), network processor, power management unit, audio processor, wireless baseband system-on-chip (SoC) processor, sensor, custom integrated circuit, memory, antenna on package (AoP), antenna in package (AiP), 5G NR millimeter-wave (mmWave) module, sub-6 GHz RF module, or integrated passive device (IPD).

In some examples, electronic component 110 can have electronic component contact pads 113 and connectors 114 at or adjacent to first electronic component side 111. In some examples, electronic component contact pads 113 can be placed between electronic component 110 and connector 114. In some examples, the active side (first electronic component side 111) of electronic component 110 can have electronic component contact pad 113 electrically connected to the circuit of electronic component 110. Electronic component contact pad 113 can meet first electronic component side 111 of electronic component 110 and the top of connector 114. For example, electronic component contact pad 113 can comprise or be referred to as a bond pad of a die exposed by SiN/SiO2 or an RDL pad exposed by a dielectric material. Electronic component contact pad 113 can help prevent separation of electronic component 110 from connector 114 under mechanical or chemical stress. In some examples, electronic component contact pads 113 can be coupled to a portion of substrate inward terminals 124a (for example, a pad or land) of inner conductive structure 124 that remains exposed through openings 125 in uppermost dielectric layer 123a. In some examples, connectors 114 can perform the coupling of electronic component 110 to substrate 120

Connectors 114 can be arranged on the underside of electronic component 110, spaced apart in rows or columns. Connectors 114 can couple inner conductive structure 124 and electronic component 110 together. Connectors 114 can comprise or be referred to as bumps, pads, or pillars, including SnPb bumps, lead-free bumps, stud bumps, or posts. In some examples, connectors 114 can be conductive bumps that couple electronic component 110 and substrate 120. Connectors 114 can be an input/output terminals of electronic component 110. In some examples, connectors 114 can be provided on first electronic component side 111 of electronic component 110 through electroplating, electroless plating, sputtering, PVD, CVD, MOCVD, ALD, LPCVD, or PECVD. For example, after a photoresist pattern exposes electronic component contact pads 113 of electronic component 110, connectors 114 can be coupled to contact pads 113. In some examples, the thickness of connectors 114 can range from approximately 1 micron to approximately 100 microns, and the width and pitch can range from approximately 10 microns to approximately 300 microns.

In some examples, electronic component 110 can be attached on top of substrate 120 through methods such as mass reflow, thermocompression bonding, direct metal-to-metal intermetallic bonding, laser soldering, conductive epoxy bonding, or conductive film bonding. Connectors 114 can electrically connect substrate 120 and the electronic component contact pads 113 of electronic component 110. In some examples, electronic component 110 can be placed near the center of substrate 120 or offset laterally from the peripheral edges of substrate 120. Contact pads 113 can comprise or be referred to as terminals.

In some examples, pick-and-place equipment can pick up electronic component 110 and position it on substrate 120. Connectors 114 of electronic component 110 can be aligned with substrate inward terminals 124a of substrate 120. Then a reflow or thermocompression process can bond connectors 114 of electronic component 110 to substrate inward terminals 124a. In some examples, electronic component 110 can be electrically connected to substrate 120 through inner conductive structure 124.

Although electronic component 110 is shown in a face-down or flip-chip configuration with contact pads 113 on the underside, electronic component 110 can also be placed in a face-up or wire-bonding configuration with contact pads 113 on the top. For example, electronic component 110 can have its active side at second electronic component side 112 and inactive side at first electronic component side 111. The inactive side can be attached to the inside of substrate 120, and the component terminals can be arranged on second electronic component side 112 containing the active side. Electronic component 110 can be a face-up or wire-bonded component. Contact pads 113 of electronic component 110 can be electrically connected to substrate inward terminals 124a of substrate 120 through connectors 114, which can comprise a conductive wire (for example, gold, copper, or aluminum wire). Wire bonding equipment can bond the component terminals of electronic component 110 to substrate inward terminals 124a. In some examples, the total thickness of electronic component 110 can range from approximately 50 microns to approximately 780 microns, and the area from approximately 0.3 millimeter (mm)×0.3 mm to approximately 70 mm×70 mm.

In some examples, electronic component 110 can be attached to substrate 120 and included in the same packaged electronic device. Optionally, additional electronic components can be provided, for example passive components, an antenna patch, or an integrated passive device (IPD). In some examples, added electronic components can be interconnected by wire bonding (WB) but other interconnect methods can be used as well.

In some examples, underfill 130 can be applied during or after attaching electronic component 110. Underfill 130 can comprise capillary underfill (CUF), Non-Conductive Paste (NCP), Non-Conductive Film (NCF), anisotropic conductive film (ACF), anisotropic conductive paste (ACP), epoxy, or a molding compound. Underfill 130 can comprise various materials, for example epoxy, thermoplastic, thermoset, polyimide, polyurethane, polymer, filled epoxy, filled thermoplastic, filled thermoset, filled polyimide, filled polyurethane, filled polymer, or fluxing underfill. The underfilling process can involve capillary underfill using a pre-applied underfill.

In some examples, underfill 130 can be located between first substrate side 121 of substrate 120 and first electronic component side 111 of electronic component 110. In some examples, if underfill 130 comprises a molded underfill (MUF), electronic component 110 can be covered with an encapsulant, and underfill 130 can be part of the encapsulant. In some examples, if underfill 130 comprises CUF, underfill material can be delivered by a narrow capillary effect between electronic component 110 and substrate 120.

FIG. 2E shows a cross-sectional view of an example final electronic device 100. In the example shown in FIG. 2E, external interconnects 150 can be provided on second substrate side 122 of substrate 120. In some examples, external interconnects 150 can be coupled to substrate outward terminals 124b through openings in lowermost dielectric layer 123b.

In some examples, external interconnects 150 can contact and be electrically connected to substrate outward terminals 124b of substrate 120. In some examples, external interconnects 150 can comprise tin (Sn), Ag, lead (Pb), Cu, Sn—Pb, Sn37-Pb, Sn95-Pb, Sn—Pb—Ag, Sn—Cu, Sn—Ag, Sn—Au, tin-bismuth (Sn—Bi), or Sn—Ag—Cu. For example, external interconnects 150 can be formed by dropping solder-containing conductive material onto substrate outward terminals 124b, followed by reflow. External interconnects 150 can comprise solder balls, bumps, pads, or pillars. In some examples, external interconnects 150 can be arranged as a ball grid array or a land grid array on second substrate side 122 of substrate 120. Sizes of external interconnects 150 can range from approximately 25 microns to approximately 1000 microns. In some examples, external interconnects 150 can be referred to as external input/output terminals of electronic device 100. External interconnects 150 can be coupled to electronic component 110 through the signal distribution structure of substrate 120.

In some examples, external interconnects 150 can have various characteristics. For example, external interconnects 150 can comprise conductive balls or bumps (for example, solder balls or bumps, wafer bumps, solid-core or copper-core solder balls). These can comprise tin, Ag, Pb, Sn—Pb, Sn37-Pb, Sn95-Pb, Sn—Pb—Ag, Sn—Pb—Bi, Sn—Cu, Sn—Ag, Sn—Au, Sn—Bi, Sn—Ag—Cu, Sn—Ag—Bi, tin-zinc (Sn—Zn), Sn—Zn—Bi, or combinations. In some examples, external interconnects 150 can also comprise conductive pillars or posts, wires, lands, or pads of a conductive material (for example, metal or conductive adhesive).

In some examples, additional components (for example, passive or active components) can be arranged laterally between external interconnects 150. In some examples, additional components can be mounted on both sides of substrate 120 in a Double-Sided Molded Ball Grid Array (DSMBGA) package or a die-size BGA (DSBGA), sometimes known as a wafer-level chip-scale package (WCSP). In one example, the additional components can have a lower height than external interconnects 150. In that situation, external interconnects 150 can provide a standoff when electronic device 100 is attached to another board or component, maintaining space for those additional parts.

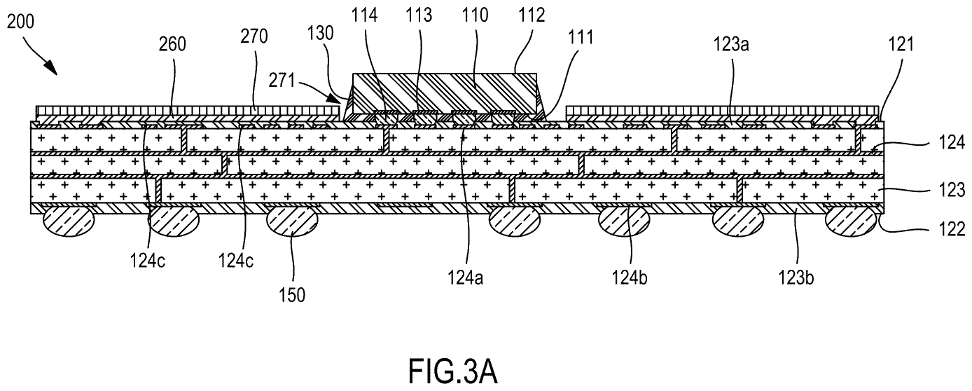

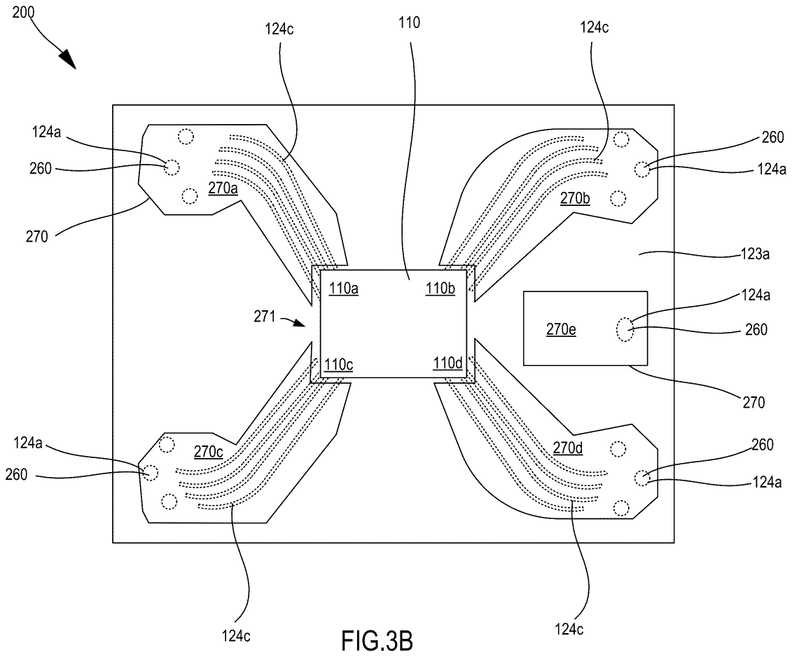

FIG. 3A shows a cross-sectional view of an example electronic device 200. In the example shown in FIG. 3A, electronic device 200 can comprise electronic component 110, substrate 120, underfill 130, external interconnects 150, adhesive layer 260, and metal layer 270.

Electronic device 200 has some similarity in construction to electronic device 100 and such similarity will not be repeated here. In this regard, only the distinctions between the two electronic devices will be discussed hereinafter. In the present example, electronic device 200 can comprise adhesive layer 260 and metal layer 270, but does not include conductive material 140. Metal layer 270 is an example of a conductive structure that can be configured as one or more of a power layer, a ground layer, a shielding structure, or a heat transfer structure. In the present example, metal layer 270 conforms to uppermost dielectric layer 123a. That is, metal layer 270 is other than a cover structure that is locally attached to substrate 120 but is otherwise spaced apart from first substrate side 121 and covers electronic component 110. In some examples, metal layer 270 contacts adhesive layer 260 along its entire lateral extent and does not extend laterally and vertically to cover electronic component 110. In the present example, conductive metal layer 270 can be a discontinuous structure and electronic component 110 can be coupled to substrate 120 through an opening 271 in conductive material 140. Opening 271 can comprise or be referred to as a gap or an outer conductive structure opening.

FIG. 3B shows a top plan view of electronic device 200. In the example shown in FIG. 3B, electronic component 110 can be placed at the center of substrate 120 and connected to substrate inward terminals 124a.

In some examples, metal layer 270 can include multiple parts or portions. In the present example, FIG. 3B illustrates metal layer 270 with portion 270a, portion, 270b, portion 270c, portion 270d, and portion 270e. In some examples, portions 270a-270d can comprise power layers and portion 270e can comprise a ground layer. Other configurations are possible with portions 270a-270e. One or more of portion 270a, portion 270b, and portion 270c can be an example of a first portion or a second portion of a conductive structure. Portion 270e can be an example of a second portion or a first portion of the conductive structure. In some examples, portions 270a-2700d are provided in a symmetrical pattern in the top plan view where each portion extends outward from a corner edge 110a, 110b, 110c, and 110d respectively of electronic component 110. In some examples, metal layer 270 only partially covers first substrate side 121 so that portions of uppermost dielectric layer 123a remain exposed from metal layer 270.

In some examples, electronic device 200 can have an arrangement where uppermost dielectric layer 123a covers the entire substrate 120, and substrate inward terminals 124a connect to metal layer 270 through adhesive layer 260 through openings 125 in uppermost dielectric layer 123a. In some examples, metal layer 270 can be positioned over substrate inward terminals 124a external to the perimeter of electronic component 110 with a gap between the lateral sides of metal layer 270 and the lateral sides of electronic component 110.

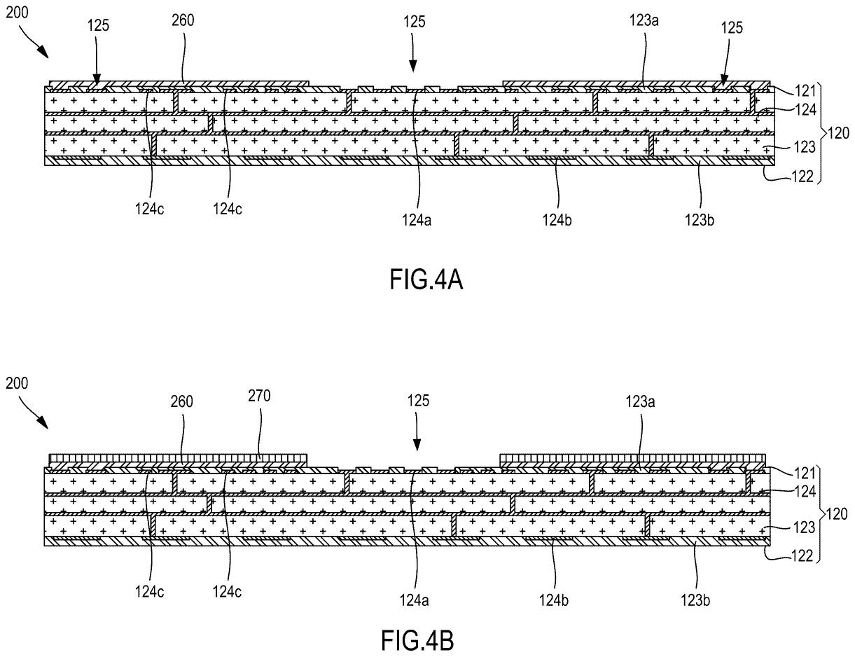

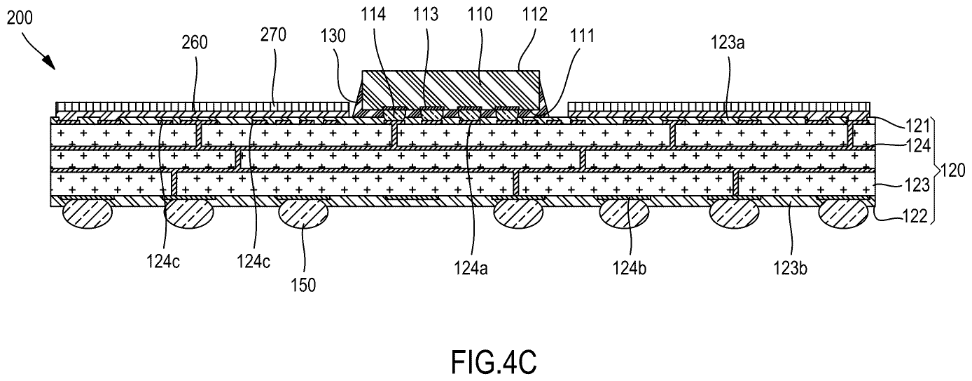

FIGS. 4A, 4B, and 4C show cross-sectional views of an example method for manufacturing an example electronic device, such as electronic device 200. FIG. 4A shows a cross-sectional view of electronic device 200 at an early stage of manufacture.

In the example shown in FIG. 4A, adhesive layer 260 can be placed on first substrate side 121 of substrate 120. In some examples, adhesive layer 260 is provided over uppermost dielectric layer 123a, within openings 125 external to where electronic component 110 will be placed on substrate 120 and is coupled to substrate inward terminals 124a. In the present example, adhesive layer 260 is configured to secure metal layer 270 to substrate 120 and to provide a conductive structure that also provides electrical connections between metal layer 270 and inner conductive structure 124. Adhesive layer 260 can be applied to the surface of substrate 120 and fill openings 125 to couple with internal wiring, creating signal or power paths and mechanically secure metal layer 270 to substrate 120.

In some examples, adhesive layer 260 can be a conductive adhesive layer containing Ag, Cu, carbon nanotubes (CNT), or a conductive polymer in a conductive paste. In other examples, adhesive layer 260 can be a non-conductive adhesive layer based on an insulating polymer (epoxy, silicone), which can require additional conductive vias to couple substrate inward terminals 124a to metal layer 270. For example, openings can be provided in adhesive layer 260 and conductive material placed in the openings before attached metal layer 270 to adhesive layer 260.

Adhesive layer 260 can secure metal layer 270 reliably, supply mechanical strength, and act as a shock-absorption or stress-relief layer. If mechanical stress or external impact applies to substrate 120, adhesive layer 260 can mitigate it and protect inner conductive structure 124. Adhesive layer 260 can connect substrate inward terminals 124a with metal layer 270 to establish power or signal paths. In some examples, the thickness of adhesive layer 260 can range from approximately 1 micron to approximately 2000 microns.

FIG. 4B shows a cross-sectional view of electronic device 200 at a later stage of manufacture. In the example shown in FIG. 4B, metal layer 270 can be placed on adhesive layer 260, enabling electrical connections and shielding on top of substrate 120. Metal layer 270 can be pressed or cured at a low temperature to increase adhesion to adhesive layer 260.

Metal layer 270 can be called a metal piece or lid. In some examples, metal layer 270 can comprise a prefabricated part or portions that are first provided and then placed onto adhesive layer 260 using, for example, pick and place processes. In some examples, metal layer 270 is other than a deposited layer. Metal layer 270 can use a highly conductive metal such as Cu, Ni, Ag, or Al. In some examples, metal layer 270 can further comprise a surface plating like Ni/Au to strengthen EMI shielding.

In some examples, metal layer 270 can be placed only where critical nets or power domains exist, supplying localized EMI shielding or power reinforcement. The shape or area of metal layer 270 can be adjusted to match package space or performance demands.

In some examples, metal layer 270 can distribute signals and power effectively compared to prior approaches. In some examples, metal layer 270 can serve as an EMI shield to reduce signal interference and improve signal quality for electronic device 200. Metal layer 270 can supply high current in power domains for stable power. Metal layer 270 can also strengthen the mechanical structure of the package and guard internal wiring from external conditions.

In some examples, metal layer 270 comprises high thermal conductivity, so it can function as a heat-dissipation path for heat generated by electronic component 110. If adhesive layer 260 has a thermal conductive filler, the combination with metal layer 270 can form an efficient heat-spreading structure for high-performance, high-heat devices. In some examples, the thickness of metal layer 270 can range from approximately 1 micron to approximately 2000 microns.

FIG. 4C shows a cross-sectional view of an example electronic device 200 after further steps in manufacture. In the example shown in FIG. 4C, adhesive layer 260 and metal layer 270 can replace conductive material 140 and conductive vias 145 of electronic device 100. In the present example, adhesive layer 260 and metal layer 270 are configured to provide improved signal integrity and power integrity for critical net and power domains. They can also provide shielding, antenna formation, or passive pattern functions in substrate 120.

The combination of adhesive layer 260 and metal layer 270 can deliver high conductivity and stability while simplifying manufacturing. Because the conductive adhesive layer connects internal wiring and the top metal layer, signal speed can increase and signal loss can decrease. EMI shielding can be boosted, raising reliability of critical nets. Metal layer 270 can provide a power path to enhance power integrity for high-current semiconductor packaging.

In some examples, attaching metal layer 270 can provide a more robust physical structure compared to better resist external shocks or mechanical stress. This can improve long-term reliability in high-temperature or high-humidity environments.

Thus, the combination of adhesive layer 260 and metal layer 270 in electronic device 200 can provide various benefits such as signal integrity, stable power delivery, EMI shielding, and optimized substrate design. Adhesive layer 260 can offer more than a basic bonding function by also providing electrical connections and signal protection. Metal layer 270 provides signal and power paths, shielding, and mechanical strength. This structure can achieve higher conductivity, reliability, simpler manufacturing, high-speed data transfers, and advanced power management in semiconductor packaging.

In summary, structures and associated methods have been described that relate to electronic devices using power/ground layers, shielding structures, or antennas as part of the substrate. More particularly, structures and methods have been described to remove power and ground layers from within the substrate and instead, provide these layers over the substrate, such as over the top side of the substrate. In this way, the substrate is devoid of power or ground layers internal to or interposed between the upper and lower sides of the substrate. The layers can be used for other functions, such as shielding, antennas, or heat transfer enhancement. In some examples, the layers can be deposited or printed onto the substrate over an uppermost dielectric layer. In some examples, the layers are coupled to substrate inward terminals using conductive vias through the uppermost dielectric layer. In some examples, the layers can be a prefabricated structure, such as a cover or lid that is attached to the substrate with an adhesive. In some examples, the adhesive comprises a conductive adhesive. The methods and structures provide reduced manufacturing cycle time, power and ground layer design flexibility, shielding or antenna options, reduced structure complexity, and reduced manufacturing costs.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a first substrate side;
a second substrate side opposite to the first substrate side;
a dielectric structure comprising an uppermost dielectric layer that defines the first substrate side; and
an inner conductive structure comprising:
substrate inward terminals proximate to the first substrate side; and
substrate outward terminals proximate to the second substrate side;
an outer conductive structure over the uppermost dielectric layer; and
an electronic component coupled to the substrate proximate to the first substrate side and coupled to the inner conductive structure;
wherein:
the uppermost dielectric layer comprises openings that expose portions of the substrate inward terminals; and
the outer conductive structure is coupled to the substrate inward terminals through the openings in the uppermost dielectric layer.

2. The electronic device of claim 1, wherein:
the outer conductive structure comprises one or more of a power layer or a ground layer;
the outer conductive structure comprises:
a conductive material; and
conductive vias coupling the conductive material to the substrate inward terminals; and
the conductive material contacts the uppermost dielectric layer and the conductive vias without laterally overlapping the electronic component.

3. The electronic device of claim 1, further comprising:
an adhesive layer;
wherein:
the outer conductive structure comprises one or more of a power layer or a ground layer;
the outer conductive structure comprises a metal layer attached to the uppermost dielectric layer with the adhesive layer; and
the metal layer contacts the adhesive layer without laterally overlapping the electronic component.

4. The electronic device of claim 3, wherein:
the adhesive layer comprises a conductive adhesive layer; and
the conductive adhesive layer is coupled to the substrate inward terminals through the openings in the uppermost dielectric layer.

5. The electronic device of claim 1, wherein:
the outer conductive structure comprises:
a first portion comprising a power layer; and
a second portion comprising a ground layer.

6. The electronic device of claim 5, wherein:
the only power layer for the electronic device consists of the first portion of the outer conductive structure; and
the only ground layer for the electronic device consists of the second portion of the outer conductive structure.

7. The electronic device of claim 1, further comprising:
external interconnects;
wherein:
the dielectric structure comprises a lowermost dielectric layer that defines the second substrate side of the substrate;
the lowermost dielectric layer comprises second openings that expose the substrate outward terminals; and
the external interconnects are coupled to the substrate outward terminals through the second openings.

8. The electronic device of claim 7, wherein:
the uppermost dielectric layer and the lowermost dielectric layer comprise polymer materials.

9. The electronic device of claim 1, wherein:
the inner conductive structure comprises signal patterns proximate to the first substrate side;
the uppermost dielectric layer covers the signal patterns; and
the outer conductive structure laterally overlaps the signal patterns.

10. The electronic device of claim 1, further comprising:
an underfill;
wherein:
the electronic component is coupled to the substrate inward terminals in a flip-chip configuration; and
the underfill is interposed between the electronic component and the first substrate side.

11. An electronic device, comprising:
a substrate comprising:
a first substrate side;
a second substrate side opposite to the first substrate side;
a dielectric structure comprising an uppermost dielectric layer that defines the first substrate side; and
an inner conductive structure comprising:
substrate inward terminals proximate to the first substrate side;
signal patterns proximate to the first substrate side; and
substrate outward terminals proximate to the second substrate side;
an outer conductive structure over the uppermost dielectric layer; and
an electronic component coupled to the substrate proximate to the first substrate side and coupled to the inner conductive structure;
wherein:
the outer conductive structure partially covers the first substrate side so that a portion of the uppermost dielectric layer is exposed from the outer conductive structure;
the uppermost dielectric layer comprises openings that expose portions of the substrate inward terminals; and
the outer conductive structure is coupled to the substrate inward terminals through the openings in the uppermost dielectric layer.

12. The electronic device of claim 11, wherein:
the outer conductive structure comprises one or more of a power layer or a ground layer;
the outer conductive structure comprises:
a conductive material; and
conductive vias coupling the conductive material to the substrate inward terminals; and
the conductive material contacts the uppermost dielectric layer and the conductive vias without laterally overlapping the electronic component.

13. The electronic device of claim 11, further comprising:
an adhesive layer;
wherein:
the outer conductive structure comprises one or more of a power layer or a ground layer;
the outer conductive structure comprises a metal layer attached to the uppermost dielectric layer with the adhesive layer; and
the metal layer contacts the adhesive layer without laterally overlapping the electronic component.

14. The electronic device of claim 11, wherein:
the outer conductive structure comprises a symmetrical pattern in a top plan view.

15. The electronic device of claim 11, wherein:
the substrate comprises a redistribution layer (RDL) substrate;
the uppermost dielectric layer covers the signal patterns; and
the outer conductive structure laterally overlaps the signal patterns.

16. A method of manufacturing an electronic device, comprising:
providing a substrate comprising:
a first substrate side;
a second substrate side opposite to the first substrate side;
a dielectric structure comprising an uppermost dielectric layer that defines the first substrate side; and
an inner conductive structure comprising:
substrate inward terminals proximate to the first substrate side;
signal patterns proximate to the first substrate side; and
substrate outward terminals proximate to the second substrate side;
providing an outer conductive structure over the uppermost dielectric layer; and
coupling an electronic component to the substrate proximate to the first substrate side and coupled to the inner conductive structure;
wherein:
the outer conductive structure comprises an outer conductive structure opening that exposes the substrate inward terminals;
the electronic component is coupled to the substrate inward terminals through the outer conductive structure opening;
the uppermost dielectric layer comprises openings that expose portions of the substrate inward terminals; and
the outer conductive structure is coupled to the substrate inward terminals through the openings in the uppermost dielectric layer.

17. The method of claim 16, wherein:
providing the outer conductive structure comprises providing one or more of a power layer or a ground layer;
the outer conductive structure comprises:
a conductive material; and
conductive vias coupling the conductive material to the substrate inward terminals; and
the conductive material contacts the uppermost dielectric layer and the conductive vias without laterally overlapping the electronic component.

18. The method of claim 16, further comprising:
providing an adhesive layer;
wherein:
providing the outer conductive structure comprises providing one or more of a power layer or a ground layer;
the outer conductive structure comprises a metal layer attached to the uppermost dielectric layer with the adhesive layer; and
the metal layer contacts the adhesive layer without laterally overlapping the electronic component.

19. The method of claim 16, wherein:
providing the outer conductive structure comprises providing a symmetrical pattern in a top plan view.

20. The method of claim 16, wherein:
providing the substrate comprises providing the uppermost dielectric layer covering the signal patterns; and
the outer conductive structure laterally overlaps the signal patterns.
